(19) United States
(12) Patent Application Publication
(10) Pub. No.: US 2017/0062714 A1
(43) Pub. Date: Mar. 2, 2017

(54) THERMALLY REGULATED ELECTRONIC DEVICES, SYSTEMS, AND ASSOCIATED METHODS

(71) Applicant: Intel Corporation, Santa Clara, CA (US)

(72) Inventor: Derchang Kau, Cupertino, CA (US)

(73) Assignee: Intel Corporation, Santa Clara, CA (US)

(21) Appl. No.: 14/841,625

(22) Filed: Aug. 31, 2015

(51) Int. Cl. H01L 45/00; H01L 27/24

(52) U.S. Cl. CPC H01L 45/1293; H01L 27/2481; H01L 45/06; H01L 27/2463; H01L 45/16

(57) ABSTRACT

Thermally-regulated electronic devices, structures, and systems having incorporated high thermal conductivity dielectric (HTCD) materials are disclosed and described, including associated methods.

### BACKGROUND

Thermal management can be a significant challenge in many electronic devices and device components. As heat builds within a device, electronic circuitry can become unreliable and prematurely fail. Various techniques have traditionally been used to remove heat from electronic devices. A heat sink, for example, is a metal or other structure that is brought into contact with a heated surface of an electronic component. Because the heat sink has a high thermal conductivity and a temperature that is cooler than the electronic component, heat energy is drawn from the heated surface and into the bulk of the heat sink. As the heat energy in the heated surface moves into the heat sink, internal heat within the device is drawn toward the heated surface, and thus the cooling of internal electronic components is achieved. Other techniques for such cooling of heated surfaces can include air cooling with fans, liquid cooling, Peltier plate cooling, and the like.

Internally, one traditional technique for cooling electronic devices is through the passive movement of heat along the conductive metal layers and vias of the electronic device. For example, heat energy is generated within internal active layers, which is thermally conducted primarily to surrounding dielectric oxide layers. As dielectric materials generally have poor thermal conductivity, the rate of conduction through these layers can be slow, thus leading to heat buildup. Metal layers used for electrical connectivity that are in contact with heated dielectric oxide layers have a much higher thermal conductivity, and thus heat will be drawn into these metal materials. Once in the metal layers, heat is much more rapidly conducted away from the heat source of the device.

### BRIEF DESCRIPTION OF THE DRAWINGS

FIG. 1a is a schematic view of a thermally-regulated electronic device in accordance with an invention embodiment;

FIG. 1b is a schematic view of a thermally-regulated electronic device in accordance with an invention embodiment;

FIG. 2 is a schematic view of a thermally-regulated electronic device in accordance with an invention embodiment;

FIG. 3 is a schematic view of a thermally-regulated electronic device in accordance with an invention embodiment;

FIG. 4 is a schematic view of a thermally-regulated electronic device in accordance with an invention embodiment;

FIG. 5a is a schematic view of a thermally-regulated multilayer interconnect in accordance with an invention embodiment;

FIG. 5b is a schematic view of a thermally-regulated multilayer interconnect in accordance with an invention embodiment;

FIG. 6a is a schematic view of a thermally-regulated multilayer interconnect being made in accordance with an invention embodiment;

FIG. 6b is a schematic view of a thermally-regulated multilayer interconnect being made in accordance with an invention embodiment;

FIG. 6c is a schematic view of a thermally-regulated multilayer interconnect being made in accordance with an invention embodiment;

FIG. 6d is a schematic view of a thermally-regulated multilayer interconnect being made in accordance with an invention embodiment;

FIG. 6e is a schematic view of a thermally-regulated multilayer interconnect being made in accordance with an invention embodiment;

FIG. 6f is a schematic view of a thermally regulated multilayer interconnect in accordance with an invention embodiment;

FIG. 7a is a schematic view of a thermally-regulated multilayer interconnect being made in accordance with an invention embodiment;

FIG. 7b is a schematic view of a thermally-regulated multilayer interconnect being made in accordance with an invention embodiment;

FIG. 7c is a schematic view of a thermally-regulated multilayer interconnect being made in accordance with an invention embodiment;

FIG. 7d is a schematic view of a thermally-regulated multilayer interconnect being made in accordance with an invention embodiment;

FIG. 7e is a schematic view of a thermally-regulated multilayer interconnect being made in accordance with an invention embodiment;

FIG. 8a is a schematic view of a thermally-regulated phase change memory array in accordance with an invention embodiment;

FIG. 8b is a schematic view of a thermally-regulated phase change memory array in accordance with an invention embodiment;

FIG. 8c is a schematic view of a thermally-regulated phase change memory array in accordance with an invention embodiment;

FIG. 8d is a schematic view of a thermally-regulated phase change memory array in accordance with an invention embodiment;

FIG. 8e is a schematic view of a thermally-regulated phase change memory array in accordance with an invention embodiment;

FIG. 8f is a schematic view of a thermally-regulated phase change memory array in accordance with an invention embodiment;

FIG. 9 is a block diagram view of a thermally-regulated phase change memory system in accordance with an invention embodiment; and

FIG. 10 is a block diagram view of a thermally-regulated computing system in accordance with an invention embodiment

### DESCRIPTION OF EMBODIMENTS

Although the following detailed description contains many specifics for the purpose of illustration, a person of ordinary skill in the art will appreciate that many variations and alterations to the following details can be made and are considered to be included herein.

Accordingly, the following embodiments are set forth without any loss of generality to, and without imposing limitations upon, any claims set forth. It is also to be understood that the terminology used herein is for the purpose of describing particular embodiments only, and is not intended to be limiting. Unless defined otherwise, all technical and scientific terms used herein have the same meaning as commonly understood by one of ordinary skill in the art to which this disclosure belongs.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the compositions nature or characteristics would be permissible if present under the “consisting essentially of” language, even though not expressly recited in a list of items following such terminology. When using an open ended term in the specification, like “comprising” or “including,” it is understood that direct support should be afforded also to “consisting essentially of” language as well as “consisting of” language as if stated explicitly and vice versa.

“The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

As used herein, “enhanced,” “improved,” “performance-enhanced,” “upgraded,” and the like, when used in connection with the description of a device or process, refers to a characteristic of the device or process that provides measurably better form or function as compared to previously known devices or processes. This applies both to the form and function of individual components in a device or process, as well as to such devices or processes as a whole.

As used herein, “coupled” refers to a relationship of physical connection or attachment between one item and another item, and includes relationships of either direct or indirect connection or attachment. Any number of items can be coupled, such as materials, components, structures, layers, devices, objects, etc.

As used herein, “directly coupled” refers to a relationship of physical connection or attachment between one item and another item where the items have at least one point of direct physical contact or otherwise touch one another. For example, when one layer of material is deposited on or against another layer of material, the layers can be said to be directly coupled.

As used herein, “indirectly coupled” refers to a relationship of connection or attachment between one item and another item where the items do not have a point of direct physical contact or do not touch one another, but rather are connected, attached, or joined together by an intermediate item. For example, when a first layer of material is bound or joined to a second layer of material using an intermediate layer in between the first and second layer, the first and second layers can be said to be indirectly coupled. A more specific example would be two layers that are bonded together using glue. In such example, each of the first and second layers would be directly coupled to the glue and indirectly coupled to one another.

As used herein “conductive,” “conductor,” and the like refer the property of a material that allows energy, such as electrical, acoustic, or thermal energy to pass or flow through it. When such terms are recited herein without a qualifier as to the type or nature of energy, (i.e. thermal, acoustic, electric, etc.), it is to be presumed that the type of energy referenced is electrical and support for the term “electrically conductive,” or “electrical conductor” and the like are to be expressly afforded unless the context clearly dictates otherwise.

Objects or structures described herein as being “adjacent to” each other may be in physical contact with each other, in close proximity to each other, or in the same general region or area as each other, as appropriate for the context in which the phrase is used.

As used herein “heat source” refers to any concentration of heat energy in a location or material that is higher than in an adjacent location or material. Heat sources can be either active or passive.

As used herein, “active heat source” refers to a concentration or collection of heat energy produced by the conversion of one form of energy into heat energy. For example, an electric current passing from a highly conductive material to a less conductive material can produce a heat concentration due to the change in electrical resistivity along the conductive pathway. As long as electric current is supplied along the conductive pathway at a sufficient level a heat concentration will be produced.

As used herein, “passive heat source” refers to a concentration or collection of heat energy received at a location downstream in a thermal pathway from an active heat source, and which can further transfer heat energy to yet another location in the thermal pathway. For example, a layer of material receiving heat energy from an active heat source directly coupled thereto can act as a passive heat source for an adjacent layer that is not directly coupled to the heat source. In some aspects, any heat concentration or collection along a thermal pathway can be a passive heat source for a location in the path which is further away from an active heat source.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. However, it is to be understood that even when the term “about” is used in the present specification in connection with a specific numerical value, that support for the exact numerical value recited apart from the “about” terminology is also provided.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

As used herein, numerical values as applied to the content of a material in a composition of materials, including numerical values relative to one another, such as ratios, can be considered to be measured in atomic % (i.e. at %).

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

### Example Embodiments

An initial overview of technology embodiments is provided below and specific technology embodiments are then described in further detail. This initial summary is intended to aid readers in understanding the technology more quickly, but is not intended to identify key or essential technological features, nor is it intended to limit the scope of the claimed subject matter.

As has been described, one traditional technique for cooling the internal circuitry of an electronic device is through the passive movement of heat along conductive metal layers and vias. Heat that is generated within internal active layers is thermally conducted primarily to surrounding dielectric oxide layers, which generally have poor thermal conductivity. Metal layers that are in thermal contact with heated dielectric oxide layers have a much higher thermal conductivity, and thus heat will be drawn into these metal materials. Once in the metal layers, heat is much more rapidly conducted away from the heat source of the device. One problem with such a method of cooling, however, relates to the continual size reduction of subsequent generations of electronic devices. As the physical dimensions of these devices are reduced, the concentration of heat sources in a given amount of area increases while the associated metal layers, interconnects, vias, and other thermally conductive materials are reduced in size and/or thickness. The result is a smaller thermal pathway for the movement of heat and a greater buildup of internal heat within the device due to the increased thermal resistance. This problem is only exacerbated in the future as the metal layers are further reduced in size, and as the reduction in substrate thickness allows for further multichip stacking.

Invention embodiments are herein provided that greatly increase the internal conduction of heat and the overall cooling of electronic devices and systems. In one embodiment, this result can be achieved by integrating a high thermal conductivity dielectric (HTCD) material or layer into an electronic device. Such an on-chip heat sink can decrease the thermal resistance and thus increase heat conduction and cooling. Such cooling improves thermal tolerance and stability during circuit operations, resulting in a decrease of negative events such as, for example, thermal disturbance in a phase change memory technology or speed throttling and performance degradation of a logic technology.

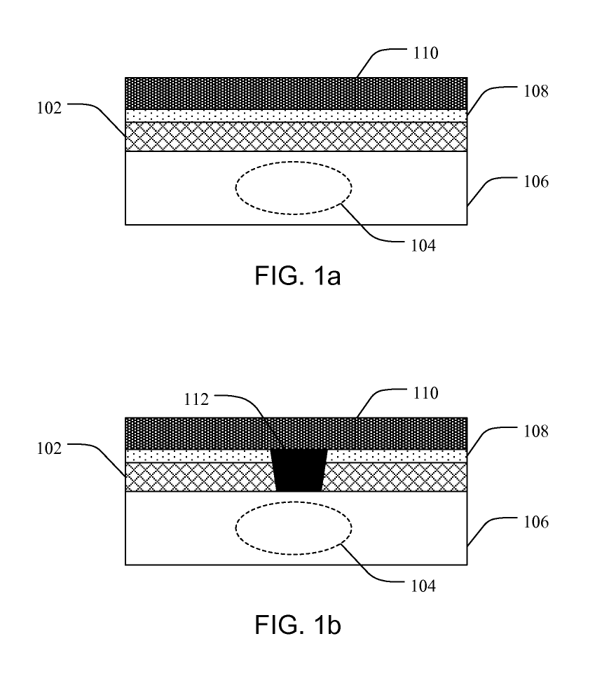

As is shown in FIG. 1a, one exemplary apparatus to provide thermal regulation to a semiconductor device includes a thermally insulating dielectric (TID) layer 102 and a heat source 104 positioned such that heat is conducted to the TID layer 102. The heat source 104 in this example is located within a substrate 106, and can include any heat source that can be present in an electronic device. The term “heat source” can include active heat sources present in the substrate, as well as heat collected in the substrate from an active heat source outside of the substrate. Non-limiting examples can include phase change materials, phase change memory cells, memory arrays, thin film switches, ovonic threshold switches, transistors, integrated circuits, resistive conductors, semiconductor junctions, LEDs, laser diodes, imagers, and the like, including combinations thereof. A high thermal conductivity dielectric (HTCD) layer 108 is coupled to the TID layer 102, and is positioned to receive and conduct heat away from the heat source 104. In this manner, the HTCD layer 108 can draw heat away from the TID layer 102 and the heat source 104, thus reduce the thermal burden on the semiconductor device. FIG. 1a further shows a conductive layer 110 coupled to the HTCD layer 108. In this configuration, the amount of heat that the conductive layer 110 experiences during operation is lowered because the HTCD layer 108 conducts heat away from the heat source 104 once it passes through the TID layer 102.

While any material or structure is contemplated, in one example the conductive layer 110 can be an electrically conductive or semiconductive material, such as, for example, a semiconductor, a doped semiconductor, a metallization layer, or other metal circuitry. Specific examples can include various non-limiting structures, such as metallization layers, contacts, vias, active semiconductor materials, integrated circuits, interconnects, multilayer interconnects, and the like, including combinations thereof. Such materials often need to be electrically insulated from other conductive or semiconductive structures to preclude inappropriate or unintended electrical conduction therebetween. As has been described, the material of the HTCD layer is a dielectric with a high thermal conductivity and a high electrical resistance. As such, the HTCD layer both electrically insulates and provides an effective thermal pathway that can conduct heat out of the device.

FIG. 1b shows one example of a device having a structure similar to FIG. 1a, but further including a via 112 positioned between the TID layer 102 and the conductive layer 110, to which the HTCD layer 108 is coupled. While vias can be utilized for electrical communication vertically through layers in a semiconductor structure, multilayer interconnect, and the like, vias can additionally function as heat sinks as well. While not always the case, substrates in many designs are thermally conductive, while dielectric layers such as the TID layer are thermal insulators. As such, for devices such as those shown in FIG. 1a-b, heat tends to be blocked within the substrate 106 by the thermally insulative TID layer 102. In this embodiment, the via 112 thus provides a focused thermal pathway for the conduction of heat from the substrate 106 to the HTCD layer 108 and the conductive layer 110.

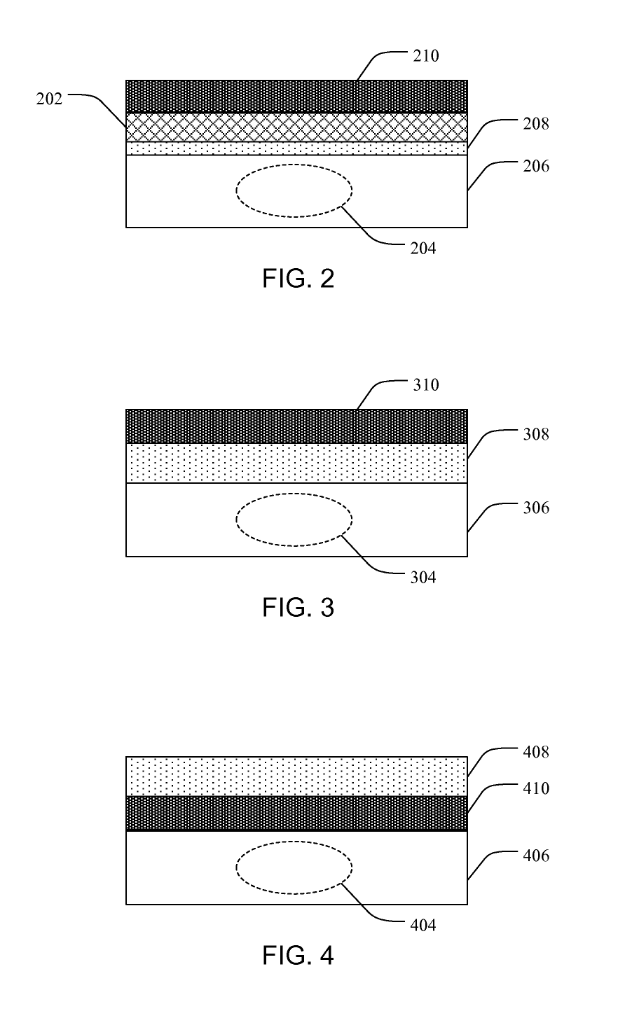

Various structural configurations of thermally regulated devices are contemplated, and any such configuration where an HTCD material is used to electrically insulate and thermally regulate an electronic device is considered to be within the present scope. As another example, shown in FIG. 2, a device can include a heat source 204 associated with a substrate 206, a TID layer 202, and an HTCD layer 208 disposed between the substrate 206 and the TID layer 202. A conductive layer 210 is shown deposited on the TID layer 202. In this example, at least a portion of the heat generated by the heat source 204 is conducted away along the HTCD layer 208 before it can reach the TID layer 202. In some cases the exemplary design of FIG. 2 can result in greater cooling because the portion of the heat that is conducted away is not required to move through the TID layer prior to reaching the HTCD layer. This design may, in some examples, thus reduce the time that a given portion of thermal energy is resident in a device.

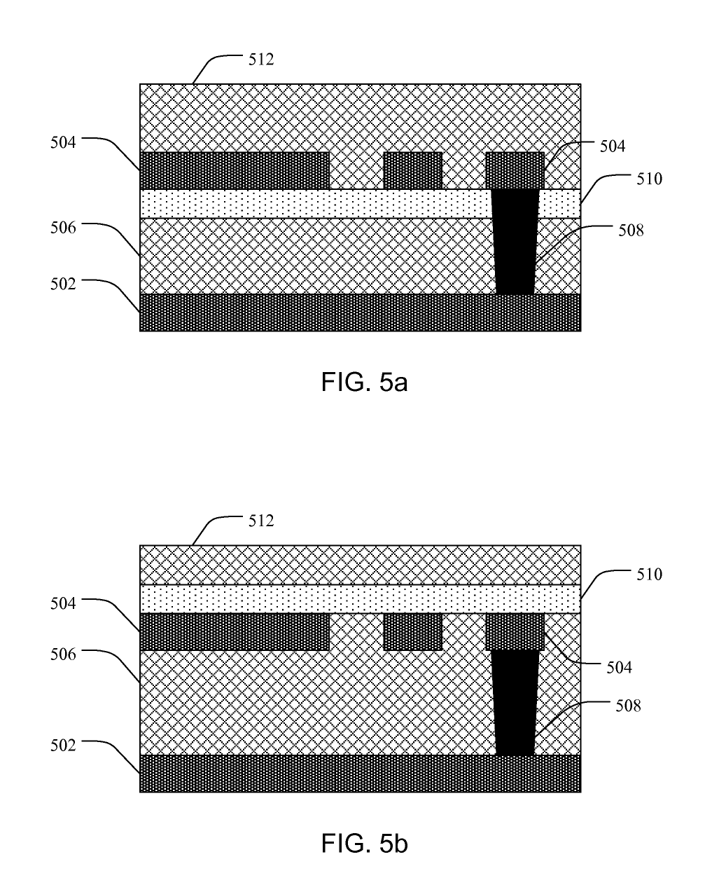

As yet another example, as is shown in FIG. 3, a device can include a heat source 304 associated with a substrate 306 and an HTCD layer 308 coupled to the substrate 306. A conductive layer 310 is shown deposited on the HTCD layer 308. In this example, at least a portion of the heat generated by the heat source 304 is conducted away along the HTCD layer 308 prior to reaching the TID layer 302.

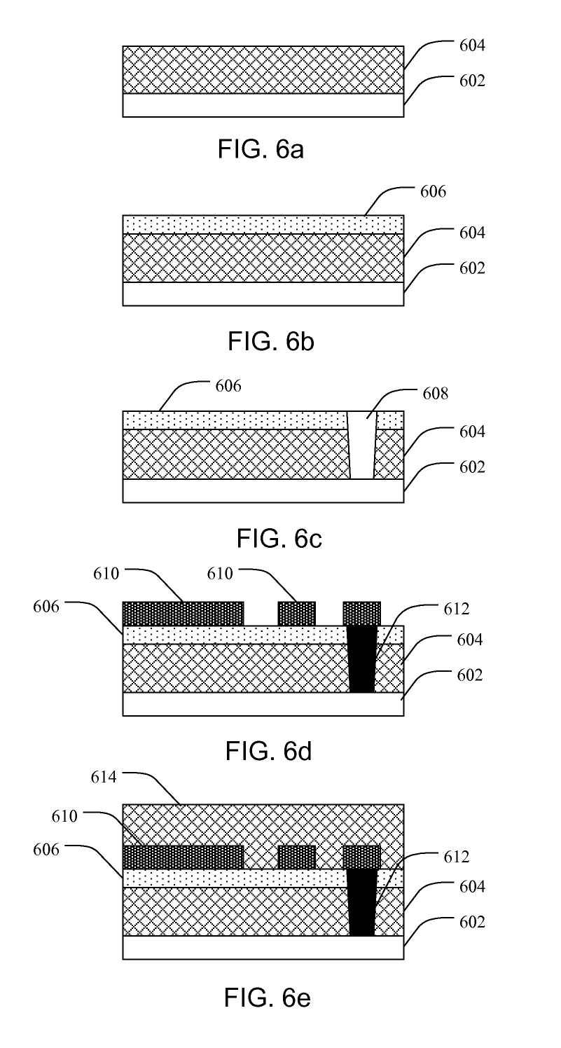

FIG. 4 shows a further example of a device having a heat source 404 associated with a substrate 406, and a conductive layer 410 coupled to the substrate 406 and positioned to directly receive heat from the heat source 404. An HTCD layer 408 is coupled to the conductive layer 410, and is positioned to draw heat from the conductive layer 410, thus cooling the device.

Various materials can be utilized as the HTCD layer, and any dielectric material having a high thermal conductivity and a high electrical resistivity, at least under operating conditions, is considered to be within the present scope. What is termed “high” thermal conductivity or “high” electrical resistivity can, in some cases, be a matter of context, and one of ordinary skill in the art could readily ascertain whether a material has a high thermal conductivity and a high electrical resistivity for a given application. In some cases, for example, high thermal conductivity may describe a material having a thermal conductivity that is sufficiently high to cause a measurable decrease in the temperature of surrounding layers, such as dielectric layers. In other aspects, high thermal conductivity can be defined as being greater than or equal to 1 W/(cm·K). Furthermore, in some cases a high electrical resistivity may describe a material having an electrical resistivity sufficiently high to preclude electrical conduction, or substantial electrical conduction, from an adjacent conductive layer under operating conditions for the device. In other cases, high electrical resistance can be defined as being greater than or equal to 10K Ohm-cm.

As such, a variety of materials can be utilized in an HTCD layer or as a component of an HTCD layer. Non-limiting examples include various metal oxides, metal nitrides, ceramics, semiconductor materials, or any other material having a high thermal conductivity and a high electrical resistance. Specific non-limiting examples can include aluminum nitride (AlN), beryllium oxide (BeO), silicon carbide (SiC), boron nitride (BN), and the like, including combinations thereof.

The overall structure and physical dimensions of the HTCD material or material layer can vary with device design, the expected thermal load on the device, and the like. In one example, however, the HTCD layer can have a minimum thickness of about 2 nm, while the maximum thickness would be as thick as the device design would allow.

HTCD materials can be integrated into an electrical device at any location where electrical insulation is desired, and such locations can vary depending on the design of the device, the thermal profile of the device structure, the intended use of the device, and the like. Thus the locations of the HTCD layers shown herein are intended to be merely exemplary. In some non-limiting examples, the HTCD layer is coupled to, or thermally coupled to (i.e. in a same thermal pathway as), a metallization layer, a contact, a via, an active semiconductor material, an integrated circuit, an interconnect, a dielectric layer, or the like, including combinations thereof. Such coupling can be direct or indirect. In one example, the HTCD layer can be coupled, including directly or indirectly, to any material or structure in the device that experiences heat buildup.

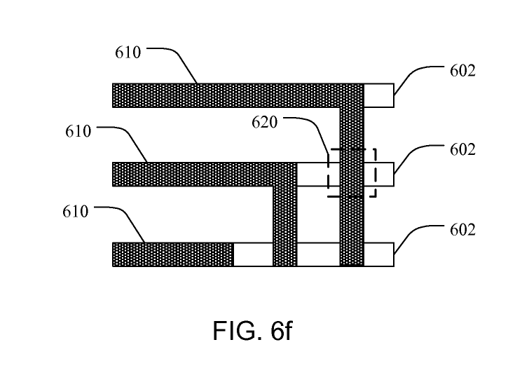

In some embodiments, it can be beneficial to integrate the HTCD layer into an interconnect, or a multilayer interconnect. Various non-limiting configurations of multilayer interconnects are contemplated, and any interconnect incorporating an HTCD layer is considered to be within the present scope. Referring to FIG. 5a, for example, one exemplary apparatus or device can include a first conductive layer 502, a second conductive layer 504, and a TID layer 506 disposed between and electrically insulating the first conductive layer 502 from the second conductive layer 504. The apparatus further includes a via 508 to provide electrical coupling between the conductive layers. An HTCD layer 510 is positioned between the second conductive layer 504 and the TID layer 506, and an additional TID layer 512 is shown disposed on the second conductive layer 504. The HTCD layer 510 is thus a heat sink within the multilayer interconnect, and can conduct heat within the structure away from high temperature regions. A similar example is shown in FIG. 5b, where the HTCD layer 510 is positioned between the second conductive layer 504 and the additional TID layer 512. It is noted that in some embodiments an HTCD layer can be positioned at the interface of the TID layer 506 and the first conductive layer 502, either instead of or in addition to the HTCD layer shown in FIG. 5a. The same is true with respect to FIG. 5b. Moreover, in some embodiments, HTCD layers can be used on either side, or on each side, of any or all TID layers and any or all conductive layers. In other embodiments, the TID layer(s) can be replaced with HTCD material in part or all together.

The thermal management of interconnects, as well as multilayer interconnects, can be utilized with any type of electronic device, structure, or system that can benefit from increasing the removal of heat. Non-limiting examples can include phase change memory, phase change switching, CMOS, SOI, and FinFET technologies, as well as a number of other transistor or other technology where heat has a tendency to build up within a device.

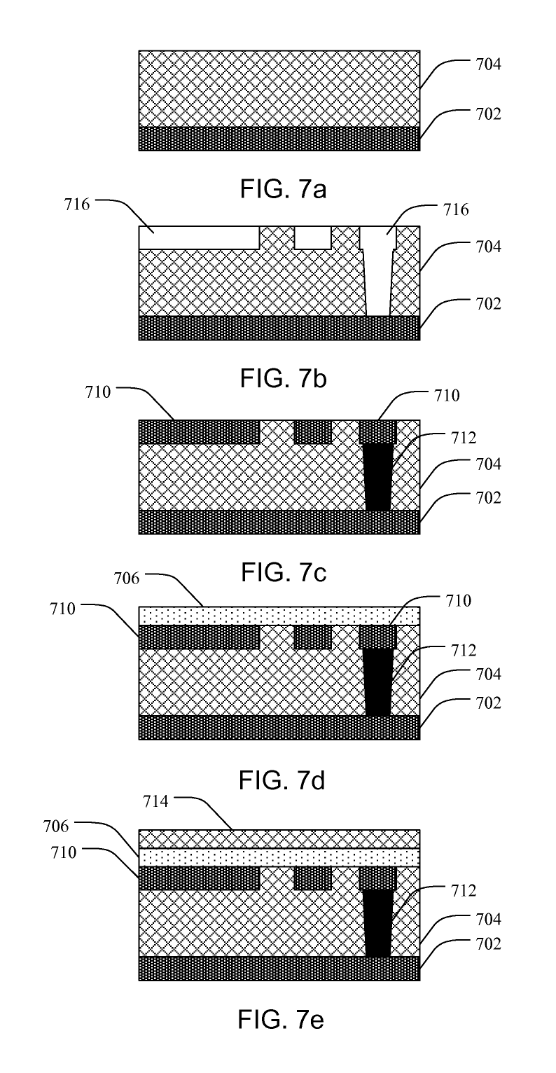

Referring to FIGS. 6a-e there is shown one example process flow of a subtractive patterning technique for forming a multilayer interconnect at specific points during a manufacturing process. As is shown in FIG. 6a, a TID layer 604 is deposited onto a surface of a first conductive layer 602. Any technique can be used for depositing the TID material, as well as any other material mentioned herein, and those skilled in the art will be able to readily identify such manufacturing methods once in possession of the present disclosure. Non-limiting examples can include various physical vapor deposition (PVD) and chemical vapor deposition (CVD) techniques, among others. In some examples an etch stop can be deposited between the first conductive layer 602 and the TID layer 604 (not shown). A HTCD layer 606 is then deposited on an exposed surface of the TID layer 604, as is shown in FIG. 6b. It is noted that this process flow can be utilized to form the HTCD layer anywhere in the multilayer structure. A trench 608 is then formed in the TID layer 604 and the HTCD layer 606 down to the first conductive layer 602, as is shown in FIG. 6c. The trench 608 can be formed by a variety of processes, including without limitation, wet etching, anisotropic etching, plasma etching, laser ablation, and the like.

Turning to FIG. 6d, the trench 608 from FIG. 6c is filled with a conductive material, such as a metal, to form a via 612 and a second conductive layer 610 is deposited onto the HTCD layer 606. Following the formation of the second conductive layer 610, an additional TID layer 614 can be deposited onto the exposed second conductive layer 610 and HTCD layer 606, as is shown in FIG. 6e. If further conductive layers are to be added to the multilayer interconnect, the additional TID layer 614 can be utilized as a substrate, and the process flow shown in FIGS. 6a-e can be repeated. It is noted that in some examples the additional TID layer 614 can include an additional HTCD layer, while in other examples the TID layer can be replaced with HTCD material (not shown). It is also noted that the HTCD layer can be positioned at any useful location within the multilayer interconnect, and as such, this example should not be seen as HI limiting. Additionally, the nature of the substrate can vary depending on the interconnect design and which portion of the interconnect is being made. As non-limiting examples, the substrate can be a semiconductor material or a dielectric material, an etch stop material, an additional HTCD layer, or an additional conductive layer, among others.

FIG. 6f shows one exemplary architecture of a top-down view of FIG. 6e. The HTCD layers, TID layers, and vias are not shown for clarity. The first conductive layers 602 and the second conductive layers 610 can be arranged in a variety of configurations, and can be included in any number and orientation in the x, y, and z directions. The HTCD material can be applied as a layer that extends across all, substantially all, or portion of a device. In some examples, an HTCD layer can be applied across at least a substantial portion of an interconnect or other electronic structure. In other examples, an HTCD layer can be applied to at least a substantial portion of TID layers capable of trapping heat, or to at least a substantial portion of any conductive or metal layer, contact, or other conductive structure. In yet other examples, an HTCD material or layer can be applied to discrete areas of a device to create heat sinks in discrete areas, such as areas having a high heat accumulation or movement, high thermal resistance, or the like. One such area, for example, is shown in FIG. 6f at 620.

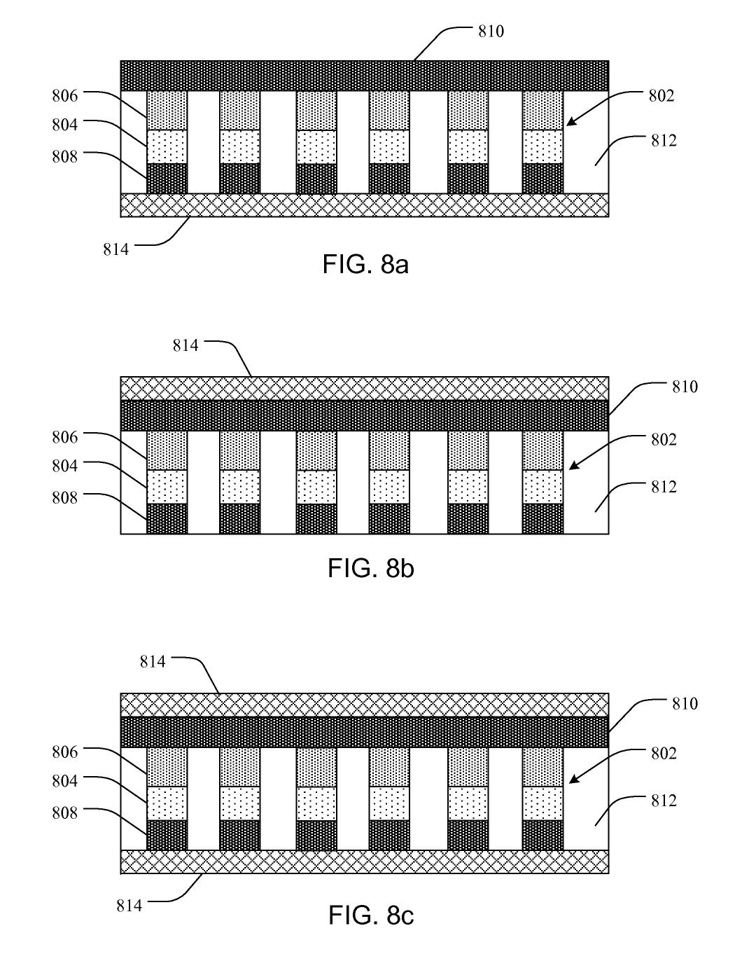

As another example, FIGS. 7a-e show a process flow for making a multilayer interconnect. As can be seen in FIG. 7a, a TID layer 704 is deposited onto a surface of a first conductive layer 702. Again any technique can be used for depositing the TID material, as well as any other material described herein, and those skilled in the art will be readily aware of such manufacturing methods once in possession of the present disclosure. Non-limiting examples can include various physical vapor deposition (PVD) and chemical vapor deposition (CVD) techniques, among others. In some examples an etch stop can be deposited between the first conductive layer 702 and the TID layer 704 (not shown). A subtractive pattern can then be applied to the TID layer 704 corresponding to an intended conductive layer pattern, and TID material is removed to create voids 716 in the TID layer 704. FIG. 7b shows the voids 716 that correspond to the intended conductive layer pattern. Turning to FIG. 7c, a conductive material such as, for example, a metal material, is deposited into the voids 716 to form the second conductive layer 710. FIG. 7c also shows a conductive pathway or via 712 between the first conductive layer 702 and the second conductive layer 710, formed therebetween by filling the void with the same or a different conductive material used to form the second conductive layer 710.

As is shown in FIG. 7d, an HTCD material is deposited on the exposed surface of the conductive layer 710 and in part on TID layer 704. It is noted that this process flow can be utilized to form the HTCD layer anywhere in the multilayer structure. Depending on the device design, in some cases an additional TID layer 714 can be deposited on the HTCD layer 706, as is shown in FIG. 7e. If further conductive layers are to be added to the multilayer interconnect, the HTCD layer 706 or the additional TID layer 714 can be utilized as a substrate, and the process flow shown in FIGS. 7a-e can be repeated. As such, the nature of the substrate can vary depending on the interconnect design and which portion of the interconnect is being made. As non-limiting examples, the substrate can be a semiconductor material or a dielectric material, an etch stop material, an additional HTCD layer, or a conductive layer, among others.

The present technology can greatly enhance the thermal management of a number of electronic circuits, devices, systems, and the like. Thermal management can be particularly challenging in electronics that generate high levels of heat, either transiently or in a sustained manner. One example of high heat electronics includes the use of phase change materials. Phase change materials can be used in a variety of applications, such as switches, memory cells, and the like. As a very general overview, phase change devices utilize materials that measurably different properties in crystalline vs. amorphous states. As such, the alterable state of the phase change material can be utilized as a mechanism for electronic switching, memory storage, computational processing, and the like.

Phase change memory cells or structures, for example, typically include a number of components in order to operate. In addition to the phase change material itself, a memory cell generally includes a pair of electrodes to provide electrical access to the phase change material, a heating element, dielectric materials, cell select devices, and the like. One class of materials useful for their phase change properties includes chalcogenides. Chalcogenide materials can include at least one element from group 16 of the periodic table, non-limiting examples of which can include sulfur (S), selenium (Se), and tellurium (Te). Specific examples of useful materials further include any of a variety of chalcogenide alloys, including, without limitation, Ge—Te, In—Se, Sb—Te, Ge—Sb, Ga—Sb, In—Sb, As—Te, Al—Te, Ge—Sb—Te, Te—Ge—As, In—Sb—Te, In—Se—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt, among others. The hyphenated chemical composition notation, as used herein, indicates the elements included in a particular mixture or compound, e.g., chalcogenide alloy, and is intended to represent all stoichiometries involving the indicated elements, e.g., GeₓSb_{y}Te_{z} having variations in stoichiometries, such as Ge₂Sb₂Te₅, Ge₂Sb₂Te₇, Ge₁Sb₂Te₄, Ge₁Sb₄Te₇, etc., to form a gradient.

The state change of a phase change material is altered using high temperatures in a controlled manner. For example, by heating a phase change material above the melting point for that material and cooling quickly, an amorphous state is achieved/maintained. When a phase change material is heated to a temperature that is higher than the glass transition temperature but below the melting point, the phase change material will solidify into the crystalline state, which has a much lower resistance compared to the amorphous state. The melting point of phase change materials varies depending on the specific material being used, but in many cases can be up to 600° C. or higher. Thus given the high melting temperatures of these materials combined with the potentially rapid programming and erase operations for a memory cell, thermal management can be an important consideration. By utilizing the presently disclosed HTCD materials at locations in a memory structure where heat can build up due to thermal resistance, phase change memory devices can be thermally managed more effectively.

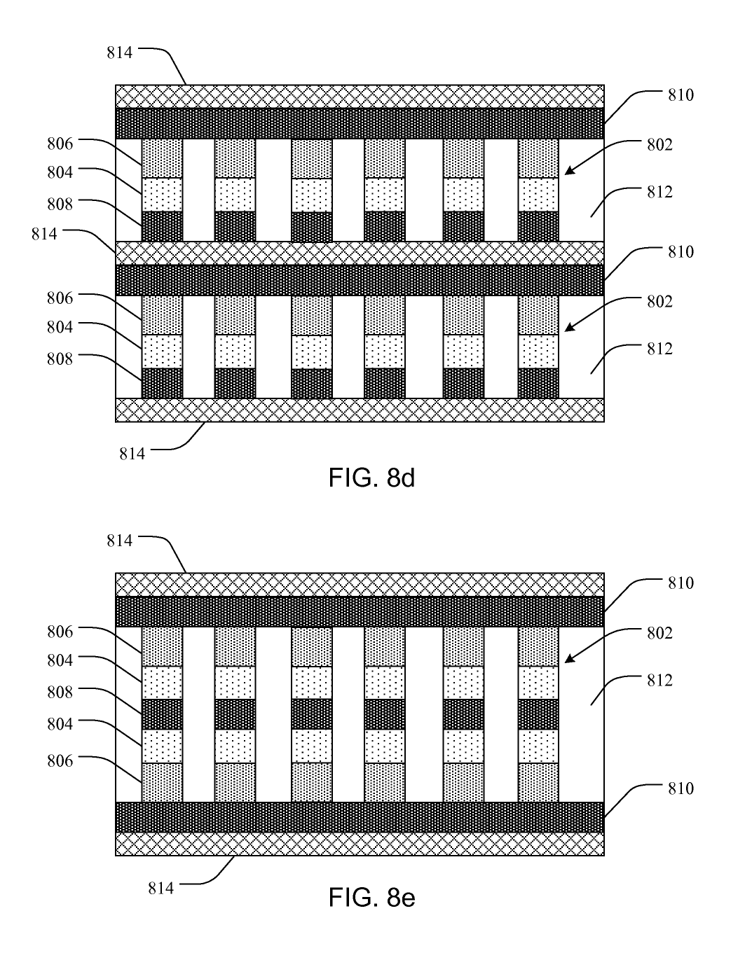

Examples of phase change memory arrays are shown in FIGS. 8a-f. Such memory arrays include a memory element 802 that further includes a phase change memory cell 804 coupled to a select (i.e. selection) device 806. The select device 806 can be any device capable of selecting and/or activating a memory cell. Non-limiting examples include an ovonic threshold switch, a semiconductor diode, or the like. A plurality of memory elements 802 are arranged in an array configuration, and are addressed at intersecting points of word lines 808 and bit lines 810. In some examples the word lines 808 and the bit lines 810 can function as electrodes, and in some cases can function as a resistive conductor or heater to control the phase change of the memory material. In other examples, distinct heating elements can be utilized. In some examples, a TID material 812 can be deposited between the memory cells 802 in the array.

The phase change memory array further includes an HTCD layer to reduce thermal buildup in the memory array, and to reduce heating spikes that can result from phase change material heating. The HTCD layer can be included in the memory array at any location that does not inhibit the functionality of the memory device. FIGS. 8a-d show examples of some possible configurations. In FIG. 8a, the HTCD layer 814 is coupled to the word lines 808, and would also be deposited across any TID material that was present between the memory cells. In this case, the HTCD layer 814 would draw heat from the word lines 808 and any TID material 812 present between the memory cells, and spread or conduct the heat away from relatively high temperature regions. In one example, the HTCD layer is directly coupled to the word lines 808. It is additionally noted that the positioning of the various layers, including the bit lines and word lines, is merely exemplary, and further architectures are contemplated where the layer ordering can be varied.

In FIG. 8b, the HTCD layer 814 is coupled to the bit lines 810 and would also be deposited across any TID material 812 that was present between the memory cells. In this case, the HTCD layer 814 would draw heat from the bit lines 810 and any TID material 812 present between the memory cells, and spread or conduct the heat away from relatively high temperature regions. In one example, the HTCD layer is directly coupled to the bit lines 810. In FIG. 8c, an HTCD layer 814 is coupled to both the word lines 808 and the bit line 810, and thus heat is drawn away from the bit lines 810, the word lines 808, and any TID material 812 present between the memory cells.

Memory cells can be arranged in an array configuration, and such array configurations can include one dimensional arrays, two dimensional arrays, and three dimensional arrays. One non-limiting example of a three dimensional memory array is shown in FIG. 8d. As with FIGS. 8a-c, the HTCD layer 814 can be coupled to, or directly coupled to, the word lines 808, the bit lines 810, or both. In such a stacked configuration, however, an HTCD layer 814 can be shared by word lines 808 and bit lines 810, and thus functions as a common heat sink for both. Additionally, FIGS. 8e-f show example embodiments where the word lines 808 is shared between adjacent stacks of memory arrays with slightly different arrangements of the memory cells 804 and the select devices 806. It is noted that the in other exemplary designs, the word lines 810 can be similarly shared, while in yet other designs both the word lines 810 and the bit lines 808 can be shared in alternating memory element 802 array stacks.

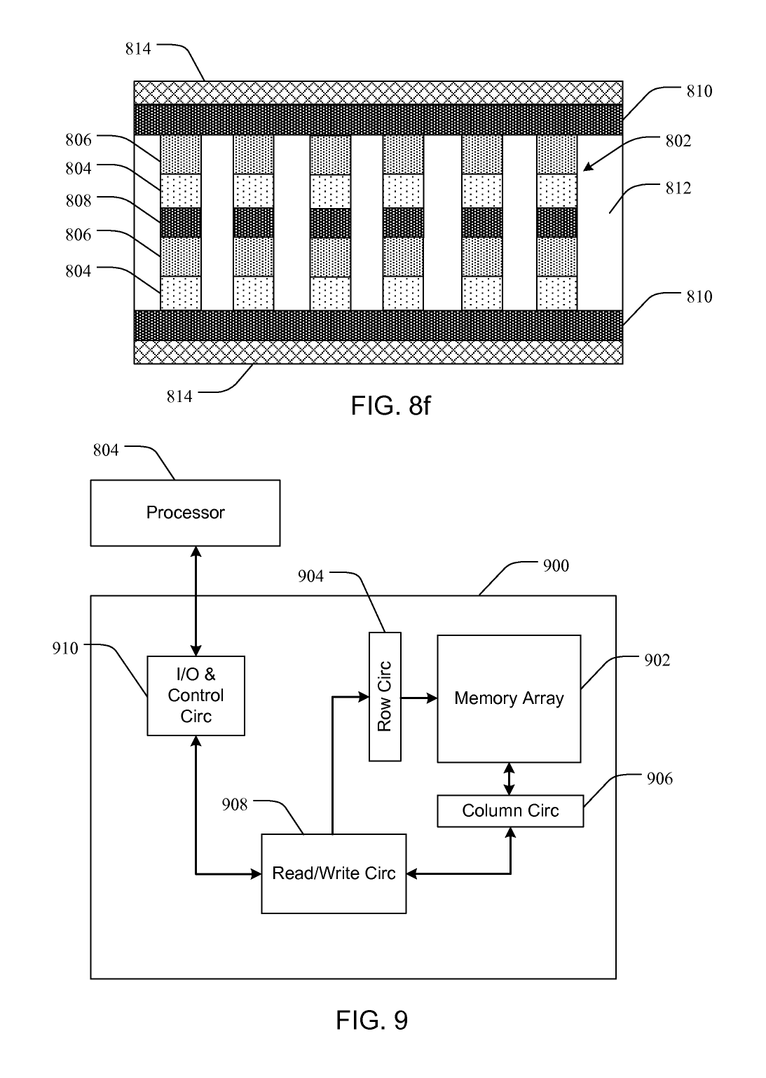

As yet another example, a thermally-regulated phase change memory system is provided. One simplified exemplary system is shown in FIG. 9. The system 900 can include a memory array 902 including a plurality of memory elements arranged in an array and including a phase change memory cell, a select device coupled to the phase change memory cell, a plurality of metallization word lines coupled to groups of phase change memory cells across the array, a plurality of metallization bit lines coupled to groups of select devices across the array such that each memory element in the array is uniquely addressed by a combination of word lines and bit lines, and an HTCD layer coupled to the plurality of memory elements and positioned to conduct the heat away therefrom. The system 900 can include row circuitry 904 coupled to the word lines of the memory array 902 and column circuitry 906 coupled to bit lines of the memory array. The column circuitry 906 and the row circuitry 904 thus function in a cooperative fashion to address each memory cell of the memory array 902. The system can also include read/write circuitry 908 coupled to the row circuitry 904 and the column circuitry 906. The read/write circuitry 908 is configured to control read and write commands to and from the memory array. Additionally, the system 900 can further include I/O circuitry 910 coupled to read/write circuitry 908. The I/O circuitry controls the I/O functions of the system, and can additionally control communications with a processor or other electronic circuits. Other circuit elements such as capacitors, junctions, or other features or structures (not shown) can be incorporated into the design of the phase change memory system and/or a larger overall system. Operation of the phase change memory system thus proceeds according to standard operation for such a device, by application of current through the system circuitry.

In a further example, a thermally-regulated memory device or system can be incorporated into a larger computing system. While any type or configuration of computing system is contemplated to be within the present scope, non-limiting examples can include a desktop computer, a laptop or notebook computer, a tablet computer, a smart phone, smart watch, handheld computer, and the like, a mainframe computer system, a server, a server bank, a workstation, a network computer, or other devices that utilize non-volatile memory.

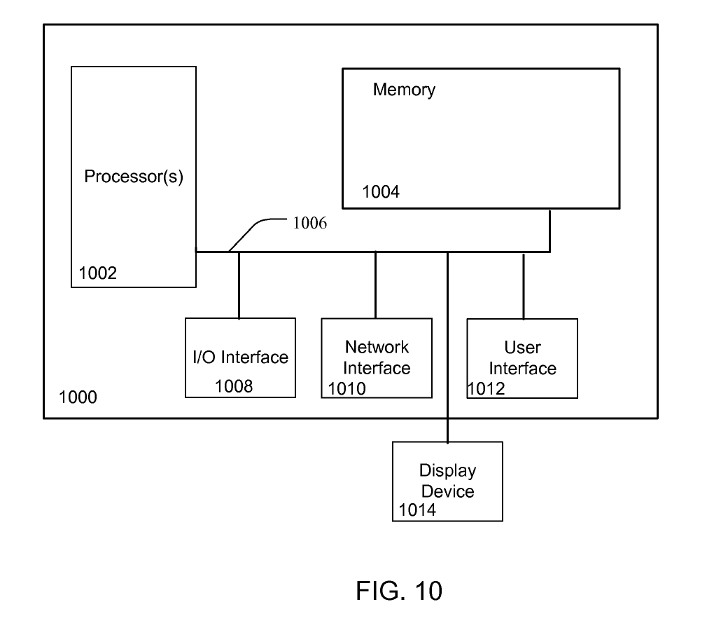

As is shown in FIG. 10, a general system 1000 can include a processor 1002 in communication with a memory 1004. One non-limiting example of at least part of a memory is shown in FIG. 9. The memory 1004 can include any device, combination of devices, circuitry, and the like that is capable of storing, accessing, organizing and/or retrieving data. Non-limiting examples include SANs (Storage Area Network), cloud storage networks, volatile or non-volatile RAM, phase change memory, optical media, hard-drive type media, and the like, including combinations thereof.

The system 1000 additionally includes a local communication interface 1006 for connectivity between the various components of the system. For example, the local communication interface 1006 can be a local data bus and/or any related address or control busses as may be desired.

The system 1000 can also include an I/O (input/output) interface 1008 for controlling the I/O functions of the system, as well as for I/O connectivity to devices outside of the system 1000. A network interface 1010 can also be included for network connectivity. The network interface 1010 can control network communications both within the system and outside of the system. The network interface can include a wired interface, a wireless interface, a Bluetooth interface, optical interface, and the like, including appropriate combinations thereof. Furthermore, the system 1000 can additionally include a user interface 1012, a display device 1014, as well as various other components that would be beneficial for such a system.

The processor 1002 can be a single or multiple processors, and the memory 1004 can be a single or multiple memories. The local communication interface 1006 can be used as a pathway to facilitate communication between any of a single processor, multiple processors, a single memory, multiple memories, the various interfaces, and the like, in any useful combination.

The following examples pertain to specific invention embodiments and point out specific features, elements, or steps that can be used or otherwise combined in achieving such embodiments.

In one example, there is provided a thermally-regulated electronic device, comprising:

a substrate;

a heat source coupled to the substrate;

a conductive layer coupled to the heat source;

a high thermal conductivity dielectric (HTCD) layer coupled to the conductive layer and positioned to conduct the heat away from the heat source and reduce a thermal burden of the device.

In one example of a device, the device can further comprise a thermally insulating dielectric (TID) layer coupled to the substrate.

In one example of a device, the TID layer is positioned between the substrate and the HTCD layer.

In one example of a device, the conductive layer is positioned between the TID layer and the HTCD layer.

In one example of a device, the HTCD layer is positioned between the conductive layer and the TID layer.

In one example of a device, the conductive layer is positioned between the TID layer and the substrate.

In one example of a device, the HTCD layer is positioned between the substrate and the TID layer.

In one example of a device, the conductive layer is positioned between the TID layer and the HTCD layer.

In one example of a device, the TID layer is positioned between the conductive layer and the HTCD layer.

In one example of a device, the conductive layer is positioned between the substrate and the HTCD layer.

In one example of a device, the conductive layer includes a structure selected from the group consisting of metallization layers, contacts, vias, active semiconductor materials, integrated circuits, interconnects, multilayer interconnects, and combinations thereof.

In one example of a device, the conductive layer comprises a metal layer.

In one example of a device, the metal layer comprises a word line or a bit line.

In one example of a device, the HTCD layer is coupled to the conductive layer.

In one example of a device, the HTCD layer is directly coupled to the conductive layer.

In one example of a device, the HTCD layer includes an HTCD material having a thermal conductivity greater than or equal to 1 W/(cm·K) and an electrical resistance greater than or equal to 10K Ohm-cm.

In one example of a device, the HTCD layer includes an HTCD material selected from the group consisting of metal oxides, metal nitrides, ceramics, and combinations thereof.

In one example of a device, the HTCD layer includes an HTCD material selected from the group consisting of aluminum nitride (AlN), beryllium oxide (BeO), silicon carbide (SiC), boron nitride (BN), and combinations thereof.

In one example of a device, the HTCD layer has a thickness sufficient to function as a heat spreader.

In one example of a device, the HTCD layer has a minimum thickness of 2 nm.

In one example of a device, the heat source is selected from the group consisting of a phase change material, a phase change memory cell, a memory array, a thin film switch, an ovonic threshold switch, a transistor, an integrated circuit, a resistive conductor, a semiconductor junction, an LED, a laser diode, an imager, and combinations thereof.

In one example of a device, the heat source comprises a semiconductor junction.

In one example of a device, the heat source comprises a resistive conductor.

In one example of a device, the heat source comprises a phase change material.

In another example, there is provided a thermally-regulated electronic device, comprising:

a substrate;

a heat source coupled to the substrate;

an interconnect layer coupled to the substrate;

a thermally insulating dielectric (TID) layer positioned to electrically insulate the interconnect; and

a high thermal conductivity dielectric (HTCD) layer coupled to the interconnect layer and positioned to spread the heat away from the heat source.

In one example of a device, the HTCD layer includes an HTCD material having a thermal conductivity greater than or equal to 1 W/(cm·K) and an electrical resistance greater than or equal to 10K Ohm-cm.

In one example of a device, the HTCD layer includes an HTCD material selected from the group consisting of metal oxides, metal nitrides, ceramics, and combinations thereof.

In one example of a device, the HTCD layer includes an HTCD material selected from the group consisting of aluminum nitride (AlN), beryllium oxide (BeO), silicon carbide (SiC), boron nitride (BN), and combinations thereof.

In one example of a device, the HTCD layer has a thickness sufficient to function as a heat spreader.

In one example of a device, the HTCD layer has a minimum thickness of 2 nm.

In one example of a device, the heat source comprises a semiconductor junction.

In one example of a device, the heat source comprises a resistive conductor.

In one example of a device, the heat source is selected from the group consisting of a phase change material, a phase change memory cell, a memory array, a thin film switch, an ovonic threshold switch, a transistor, an integrated circuit, a resistive conductor, a semiconductor junction, an LED, a laser diode, an imager, and combinations thereof.

In a further example, there is provided a thermally-regulated electronic device, comprising:

a substrate;

a heat source coupled to the substrate;

a multilayer interconnect coupled to the substrate including a plurality of metal layers;

a thermally insulating dielectric (TID) layer positioned to electrically insulate the plurality of metal layers; and

a high thermal conductivity dielectric (HTCD) layer coupled to the multilayer interconnect and positioned to spread the heat laterally relative to the multilayer interconnect.

In one example of a device, a portion of the HTCD layer is positioned between adjacent pairs of metal layers in the multilayer interconnect.

In one example of a device, a portion of the HTCD layer is positioned between each adjacent pair of metal layers in the multilayer interconnect.

In one example of a device, each of the plurality of metal layers is in direct contact with an adjacent portion of the HTCD layer.

In one example of a device, the HTCD layer includes an HTCD material having a thermal conductivity greater than or equal to 1 W/(cm·K) and an electrical resistance greater than or equal to 10K Ohm-cm.

In one example of a device, the HTCD layer includes an HTCD material selected from the group consisting of metal oxides, metal nitrides, ceramics, and combinations thereof.

In one example of a device, the HTCD layer includes an HTCD material selected from the group consisting of aluminum nitride (AlN), beryllium oxide (BeO), silicon carbide (SiC), boron nitride (BN), and combinations thereof.

In one example of a device, the HTCD layer has a thickness sufficient to function as a heat spreader.

In one example of a device, the HTCD layer has a minimum thickness of 2 nm.

In one example of a device, the heat source comprises a semiconductor junction.

In one example of a device, the heat source comprises a resistive conductor.

In one example of a device, the heat source is selected from the group consisting of a phase change material, a phase change memory cell, a memory array, a thin film switch, an ovonic threshold switch, a transistor, an integrated circuit, a resistive conductor, a semiconductor junction, an LED, a laser diode, an imager, and combinations thereof.

In one example, there is provided a thermally-regulated memory array, comprising:

a plurality of memory elements arranged in an array and including;

a memory cell; and

a select device coupled to the memory cell;

a plurality of metallization word lines coupled to groups of memory cells across the array;

a plurality of metallization bit lines coupled to groups of select devices across the array such that each memory element is uniquely addressed in the array by a combination of word lines and bit lines; and

a high thermal conductivity dielectric (HTCD) layer coupled to the plurality of memory elements and positioned to conduct the heat away from the memory elements.

In one example of an array, the HTCD layer is coupled to the word lines.

In one example of an array, the HTCD layer is coupled to the bit lines.

In one example of an array, the HTCD layer is coupled to both the word lines and the bit lines.

In one example of an array, the memory cell comprises a phase change memory cell.

In one example of an array, the select device comprises an ovonic threshold switch or a semiconductor diode.

In one example of an array, the word lines and the bit lines are electrodes operable to deliver sufficient current to operate the phase change memory cell.

In one example of an array, the array comprises a two dimensional array.

In one example of an array, the array comprises a three dimensional array.

In one example, there is provided a thermally-regulated phase change memory system, comprising:

a memory array further comprising:

a plurality of memory elements arranged in an array and including;

a phase change memory cell; and

a select device coupled to the phase change memory cell;

a plurality of metallization word lines coupled to groups of phase change memory cells across the array;

a plurality of metallization bit lines coupled to groups of select devices across the array such that each memory element is uniquely addressed in the array by a combination of word lines and bit lines; and

a high thermal conductivity dielectric (HTCD) layer coupled to the plurality of memory elements and positioned to conduct the heat away from the memory elements;

circuitry electrically coupled to the memory array and configured to:

generate memory control commands;

address the phase change memory cells in the array; and

read a state of each phase change memory cell.

In one example of a system, the HTCD layer is coupled to the word lines.

In one example of a system, the HTCD layer is coupled to the bit lines.

In one example of a system, the HTCD layer is coupled to both the word lines and the bit lines.

In one example of a system, the select device comprises an ovonic threshold switch or a semiconductor diode.

In one example of a system, the word lines and the bit lines are electrodes operable to deliver sufficient current to operate the phase change memory cell.

In one example of a system, the system further comprises a power source coupled to the circuitry and to the memory array.

In one example of a system, the memory array comprises a two dimensional array.

In one example of a system, the memory array comprises a three dimensional array.

In one example of a system, the circuitry further comprises I/O circuitry configured to control I/O operations of the memory array system.

In one example of a system, the I/O circuitry is configured to communicate with a processor.

In one example of a system, the circuitry further comprises:

row circuitry coupled to the word lines of the memory array; and column circuitry coupled to bit lines of the memory array, the column circuitry and the row circuitry being configured to address the plurality of memory cells of the memory array.

In one example of a system, the circuitry further comprises read/write circuitry coupled to the row circuitry and the column circuitry and configured to control read and write commands to and from the memory array.

In one example, there is provided a method for making a thermally-regulated multilayer interconnect, comprising:

depositing a thermally insulating dielectric (TID) layer on a substrate;

depositing a high thermal conductivity dielectric (HTCD) layer on the TID layer;

depositing a metal layer of a multilayer interconnect on the HTCD layer.

In one example of a method, the substrate comprises a semiconductor material.

In one example of a method the substrate comprises an etch stop material.

In one example of a method the substrate comprises an additional metal layer.

In one example of a method, the method further comprises forming a via through the HTCD layer and the TID layer prior to depositing the metal layer on the HTCD layer.

In one example of a method, the method further comprises the previously recited method steps to form a subsequent metal layer of the multilayer interconnect.

In one example, there is provided a method for making a thermally-regulated multilayer interconnect, comprising:

depositing a thermally insulating dielectric (TID) layer on a substrate;

applying a subtractive pattern to the TID layer corresponding to a desired metallization pattern;

removing a portion of the TID layer to create voids corresponding to the metallization pattern;

depositing a metal material into the voids to form a metal layer of the multilayer interconnect; and

depositing a high thermal conductivity dielectric (HTCD) layer on the exposed T ID and metal layers.

In one example of a method, the method further comprises depositing an additional TID layer on the HTCD layer.

In one example of a method, the substrate comprises a semiconductor material.

In one example of a method, the substrate comprises an etch stop material.

In one example of a method, the substrate comprises an additional HTCD layer.

In one example of a method, the substrate comprises an additional metal layer.

In one example of a method, removing the portion of the TID layer to create the voids and depositing the metal material into the voids includes forming at least one via.

What is claimed is:

1. A thermally-regulated electronic device, comprising:
a substrate;
a heat source coupled to the substrate;
a multilayer interconnect coupled to the substrate including a plurality of metal layers;
a thermally insulating dielectric (TID) layer positioned to electrically insulate the plurality of metal layers; and
a high thermal conductivity dielectric (HTCD) layer coupled to the multilayer interconnect and positioned to spread the heat laterally relative to the multilayer interconnect.

2. The device of claim 1, wherein a portion of the HTCD layer is positioned between adjacent pairs of metal layers in the multilayer interconnect.

3. The device of claim 1, wherein a portion of the HTCD layer is positioned between each adjacent pair of metal layers in the multilayer interconnect.

4. The device of claim 3, wherein each of the plurality of metal layers is in direct contact with an adjacent portion of the HTCD layer.

5. The device of claim 1, wherein the HTCD layer includes an HTCD material having a thermal conductivity greater than or equal to 1 W/(cm·K) and an electrical resistance greater than or equal to 10K Ohm-cm.

6. The device of claim 5, wherein the HTCD layer includes an HTCD material selected from the group consisting of metal oxides, metal nitrides, ceramics, and combinations thereof.

7. The device of claim 5, wherein the HTCD layer includes an HTCD material selected from the group consisting of aluminum nitride (AlN), beryllium oxide (BeO), silicon carbide (SiC), boron nitride (BN), and combinations thereof.

8. The device of claim 1, wherein the HTCD layer has a thickness sufficient to function as a heat spreader.

9. The device of claim 1, wherein the HTCD layer has a minimum thickness of 2 nm.

10. The device of claim 1, wherein the heat source comprises a semiconductor junction.

11. The device of claim 1, wherein the heat source comprises a resistive conductor.

12. The device of claim 1, wherein the heat source is selected from the group consisting of a phase change material, a phase change memory cell, a memory array, a thin film switch, an ovonic threshold switch, a transistor, an integrated circuit, a resistive conductor, a semiconductor junction, an LED, a laser diode, an imager, and combinations thereof.

13. A thermally-regulated phase change memory system, comprising:
a memory array further comprising:
a plurality of memory elements arranged in an array and including;
a phase change memory cell; and
a select device coupled to the phase change memory cell;
a plurality of metallization word lines coupled to groups of phase change memory cells across the array;
a plurality of metallization bit lines coupled to groups of select devices across the array such that each memory element is uniquely addressed in the array by a combination of word lines and bit lines; and
a high thermal conductivity dielectric (HTCD) layer coupled to the plurality of memory elements and positioned to conduct the heat away from the memory elements;
circuitry electrically coupled to the memory array and configured to:
generate memory control commands;
address the phase change memory cells in the array; and
read a state of each phase change memory cell.

14. The system of claim 13, wherein the HTCD layer is coupled to the word lines.

15. The system of claim 13, wherein the HTCD layer is coupled to the bit lines.

16. The system of claim 13, wherein the HTCD layer is coupled to both the word lines and the bit lines.

17. The system of claim 13, wherein the select device comprises an ovonic threshold switch or a semiconductor diode.

18. The system of claim 13, wherein the word lines and the bit lines are electrodes operable to deliver sufficient current to operate the phase change memory cell.

19. The system of claim 13, further comprising a power source coupled to the circuitry and to the memory array.

20. The system of claim 13, wherein the memory array comprises a two dimensional array.

21. The system of claim 13, wherein the memory array comprises a three dimensional array.

22. The system of claim 13, wherein the circuitry further comprises I/O circuitry configured to control I/O operations of the memory array system.

23. The system of claim 13, wherein the I/O circuitry is configured to communicate with a processor.

24. The system of claim 13, wherein the circuitry further comprises:
row circuitry coupled to the word lines of the memory array; and
column circuitry coupled to bit lines of the memory array, the column circuitry and the row circuitry being configured to address the plurality of memory cells of the memory array.

25. The system of claim 13, wherein the circuitry further comprises read/write circuitry coupled to the row circuitry and the column circuitry and configured to control read and write commands to and from the memory array.

26. A method for making a thermally-regulated multilayer interconnect, comprising:
depositing a thermally insulating dielectric (TID) layer on a substrate;
applying a subtractive pattern to the TID layer corresponding to a desired metallization pattern;
removing a portion of the TID layer to create voids corresponding to the metallization pattern;
depositing a metal material into the voids to form a metal layer of the multilayer interconnect; and
depositing a high thermal conductivity dielectric (HTCD) layer on the exposed T ID and metal layers.

27. The method of claim 26, further comprising depositing an additional TID layer on the HTCD layer.

28. The method of claim 26, wherein the substrate comprises a semiconductor material.

29. The method of claim 26, wherein the substrate comprises an additional HTCD layer.

30. The method of claim 26, wherein the substrate comprises an additional metal layer.
